(19) United States
(12) Patent Application Publication
(10) Pub. No.: US 2007/0018198 A1
(43) Pub. Date: Jan. 25, 2007

(54) High electron mobility electronic device structures comprising native substrates and methods for making the same

(76) Inventors: George R. Brandes, Raleigh, NC (US); Xueping Xu, Stamford, CT (US); Joseph Dion, Broad Brook, CT (US); Robert P. Vaudo, Cary, NC (US); Jeffrey S. Flynn, Raleigh, NC (US)

Correspondence Address: INTELLECTUAL PROPERTY / TECHNOLOGY LAW, PO BOX 14329, RESEARCH TRIANGLE PARK, NC, 27709, US

(21) Appl. No.: 11/186,001

(22) Filed: Jul. 20, 2005

(51) Int. Cl. H01L 29/732

(52) U.S. Cl. 257/183

(57) ABSTRACT

An electronic device structure comprises a substrate layer of semi-insulating AlₓGa_{y}In_{z}N, a first layer comprising AlₓGa_{y}In_{z}N, a second layer comprising Al_{x′}Ga_{y′}In_{z′}N, and at least one conductive terminal disposed in or on any of the foregoing layers, with the first and second layers being adapted to form a two dimensional electron gas is provided. A thin (<1000 nm) III-nitride layer is homoepitaxially grown on a native semi-insulating III-V substrate to provide an improved electronic device (e.g., HEMT) structure.

### GOVERNMENT RIGHTS IN INVENTION

Work relevant to the subject matter hereof was conducted in the performance of DARPA Contract No. N00014-02-C-0321. The United States government may have certain rights in this invention.

### FIELD OF THE INVENTION

The present invention relates to electronic device (e.g., high electron mobility transistor) structures including III-nitride device layers grown on native insulating substrates and methods for making the same.

### DESCRIPTION OF THE RELATED ART

Gallium nitride and related III-V alloys have exhibited great potential for high power and/or high frequency electronic applications. Particularly desirable applications include high electron mobility transistors (HEMTs), which are electronic devices having three terminals including a gate, a drain, and a source. Electric potential on the gate controls the current flow between the source and the drain. AlGaN/GaN heterostructure-based HEMTs are of interest because a two-dimensional electron gas (2DEG, also referred to as the channel charge) that enhances electron transport capability is spontaneously formed along the heterointerface.

Due to a lack of large-area, high quality native GaN substrates, conventional GaN-based HEMT devices have been grown on non-native (heteroepitaxial) substrates such as sapphire and silicon carbide. Owing to the potentially severe lattice mismatches between substrates and buffers, nucleation layers consisting of AlN, GaN, or AlGaN are routinely used in an attempt to improve the GaN buffers to the substrates. Nucleation layers are typically AlN or AlGaN. The criticality of improving GaN buffer quality to reduce strain renders the engineering of nucleation layers one of the most critical steps in fabrication of GaN-based HEMT devices.

Among various examples of GaN-based HEMT devices, U.S. Pat. No. 5,192,987 to Khan et al. discloses a HEMT structure utilizing a sapphire substrate in which an AlN buffer layer is first deposited on the sapphire substrate, a GaN layer is deposited on the AlN buffer layer, and an AlGaN layer is deposited on the GaN layer. U.S. Pat. No. 6,316,793 to Sheppard et al. discloses HEMTs based on AlGaN/GaN heterostructures grown on silicon carbide substrates.

A multi-layer structure 1 for use in a conventional HEMT is illustrated in FIG. 1. A nucleation layer 13 is grown on a substrate 10 of sapphire or silicon carbide. A GaN layer 20 having a typical thickness of about two to three microns is grown on the nucleation layer 13. Thereafter, an AlGaN layer 30 is grown on the GaN to form a 2DEG at the interface between the two nitride layers 20, 30. Various modifications of these basic AlGaN/GaN HEMT structures are disclosed, for example, in U.S. Pat. No. 6,534,801 to Yoshida, in U.S. Pat. No. 6,548,333 to Smith, and in U.S. Pat. No. 6,624,453 to Yu et al. Despite the use of nucleation layers, crystal quality of an epitaxial device layer grown on a foreign substrate is inferior to the epitaxial device layer that would be grown on a crystalline native substrate. It would be advantageous to grow high quality AlGaN/GaN device layers on native insulating substrates. Homoepitaxial growth on high crystalline quality native substrates offers the potential of producing device layers with significantly reduced crystalline defects compared with their counterpart device layers grown on non-native substrate materials. A reduced defect density substantially enhances device performance (e.g., leakage current reduction, PAE increase, Pout increase, noise reduction, etc.) and lifetime (e.g., increased mean time between failure, reduced device break-in effects). Furthermore, homoepitaxial device layer growth on native substrates would substantially eliminate the stress arising from thermal expansion differences between the foreign substrate and GaN device layers, improving the device performance and yield. Due to the inferiority of epitaxial device layers grown on foreign substrates, the intrinsic material potential of AlGaN/GaN systems is not realized in conventional HEMTs.

Insulating native III-nitride (e.g., GaN) substrate materials have recently become known. For example, commonly assigned U.S. Patent Publication No. 2005/0009310 (published Jan. 13, 2005) for “Semi-insulating GaN and method of making the same” discloses methods for making large-area single-crystal semi-insulating GaN (“SI GaN”). Applicants have experimented with various methods for using SI GaN as a substrate material for HEMT devices fabricated with epitaxial device layers. Surprisingly, Applicants have found that when homoepitaxial GaN layers are grown on native SI GaN substrates using conventional methods, an unforeseen problem arises: the formation of unintended non-channel charge. While a HEMT desirably has a single conductive channel along an AlGaN/GaN interface (the 2DEG), attempts to construct HEMT devices by homoepitaxial growth of nitride layers on native SI GaN substrates have caused non-channel charge to form well apart from (e.g., below) the 2DEG. It is believed that the non-channel charge may be formed in close proximity to the interface between a GaN epilayer and a SI GaN substrate. While the precise cause of non-channel charge is not fully understood, it is believed that such charge is due at least in part to the presence of impurities such as silicon and oxygen in the interfacial region. The increased impurity concentration possibly arises from differences in growth mode, process conditions, and compensation mechanism differences between the growth of SI GaN and the epitaxial growth of GaN on SI GaN, and/or by the presence of surface preparation residue remaining on the SI GaN. It is also possible that non-channel charge is generated by piezoelectric properties from strain and other structural defects within the initial epitaxial layer and/or along the interface between the epitaxial layer and the substrate.

Non-channel charge is undesirable in HEMT devices, for example, because it provides an alternative current flow path outside of the 2DEG, with the alternative current flow path being difficult to pinch off using conventional gate formulations and operating conditions. Consequently, the presence of non-channel charge renders it difficult to modulate current in any resulting HEMT device, substantially limiting its utility.

In consequence, the art continues to seek improvement in high electron mobility electronic device structures. It would be desirable to fabricate high electron mobility device structures using native substrates, and for the resulting structures to be substantially free of uncontrollable non-channel charge effects.

### SUMMARY OF THE INVENTION

The present invention relates to electronic device structures including high quality III-nitride layers grown on native insulating III-V substrates and at least one terminal comprising a conductive material, and methods for making these structures. The resulting structures are suitable for use in high electron mobility transistors, electronic/microelectronic devices, and corresponding device precursor structures.

In one aspect, the invention relates to an electronic device structure having a substrate layer including a semi-insulating AlₓGa_{y}In_{z}N material, wherein 0≦x≦1, 0≦y≦1, 0≦z≦1, and x+y+z=1; a first layer including an AlₓGa_{y}In_{z}N material; a second layer including an Al_{x′}Ga_{y′}In_{z′}N material, wherein 0≦x′≦1, 0≦y′≦1, 0≦z′≦1, and x′+y′+z′=1; and at least one terminal including a conductive material. The first layer is disposed between the second layer and the substrate, with the materials of the first and second layers being adapted to form a two-dimensional electron gas along the heterointerface. Lattice matching between the first layer and the substrate may be achieved without the use of an intermediate nucleation layer. The first layer thickness is preferably less than about 1000 nanometers, more preferably less than about 500 nanometers, and still more preferably less than about 200 nanometers.

In another aspect, the invention relates to an electronic device structure having a semi-insulating substrate layer, first and second layers adapted to form a two-dimensional electron gas, and at least one terminal including a conductive material. The substrate includes a first III-nitride material and a dopant, the first layer includes the first III-nitride material, and the second layer includes a second III-nitride material.

In another aspect, the invention relates to an electronic device structure having substrate layer including a semi-insulating first III-nitride material, an epitaxially grown first layer including the first III-nitride material that is lattice-matched to the substrate layer, an epitaxially grown second layer including a second III-nitride material, and at least one terminal including a conductive material. The first layer and the second layer define a heterojunction adapted to form a two dimensional electron gas.

In another aspect, the invention relates to a method of fabricating an electronic device structure including several method steps. A first method step includes providing a semi-insulating substrate including an AlₓGa_{y}In_{z}N material (wherein 0≦x≦1, 0≦Y≦1, 0≦z≦1, and x+y+z=1). A second method step includes epitaxially growing a first layer including the AlₓGa_{y}In_{z}N material on or adjacent to the substrate. A third method step includes epitaxially growing a second layer including an Al_{x′}Ga_{y′}In_{z′}N, material (wherein 0≦x′≦1, 0≦y′≦1, 0≦z′≦1, and x′+y′+z′=1) on or adjacent to the first layer, with the first layer and second layer being adapted to form a two dimensional electron gas. A fourth method step includes depositing at least one terminal in electrical contact with the two dimensional electron gas.

Other aspects, features and embodiments of the invention will be more fully apparent from the ensuing disclosure and appended claims.

### BRIEF DESCRIPTION OF THE DRAWINGS

In the drawings, like numbers are intended to refer to like elements or structures. None of the drawings are drawn to scale unless indicated otherwise.

FIG. 1 is a cross-sectional schematic illustration of a conventional multi-layer electronic structure suitable for use in a HEMT, the structure including an AlGaN layer, a GaN layer, a nucleation layer, and a foreign substrate.

FIG. 2A is a cross-sectional schematic illustration of a multi-layer electronic structure according to a first embodiment, the structure including a substrate of an insulating first III-nitride material [selected from AlₓGa_{y}In_{z}N, wherein 0≦x≦1, 0≦y≦1, 0≦z≦1, and x+y+z=1], a first layer of the first III-nitride material, and a second layer of a second III-nitride material [selected from Al_{x′}Ga_{y′}In_{z′}N, wherein 0≦x′≦1, 0≦y′≦1, 0≦z′≦1, and x+y+z=1] different from the first III-nitride material and adapted to form a two-dimensional electron gas along the heretointerface of the first and second layers.

FIG. 2B is a cross-sectional schematic illustration of a subset of the multi-layer electronic structure according to the first embodiment in which the insulating first III-nitride material includes semi-insulating GaN, the first III-nitride material includes GaN, and the second III-nitride material includes AlGaN.

FIG. 3 is a cross-sectional schematic illustration of the multi-layer electronic structure of FIG. 2B with the addition of conductive source and drain terminals and an electrically isolated gate terminal to form a HEMT.

FIG. 4 is a schematic illustration of an electronic device incorporating a multi-layer electronic device structure such as illustrated in FIG. 2A or 2B.

FIG. 5 is a cross-sectional schematic illustration of a multi-layer electronic structure according to a second embodiment, the structure having a semi-insulating GaN substrate, a first layer of GaN, a second layer of AlGaN, and a third (cap) layer of GaN, with a 2DEG formed along or adjacent to the heterojunction between the first and second layers.

FIG. 6 is a cross-sectional schematic illustration of a multi-layer electronic structure according to a third embodiment substantially similar to the second embodiment illustrated in FIG. 5, but with the addition of a nanolayer of AlN disposed between the first layer of GaN and the second layer of AlGaN, with a 2DEG formed along or adjacent to the thin layer of AlN.

FIG. 7 is a cross-sectional schematic illustration of a multi-layer electronic structure according to a fourth embodiment, the structure including a semi-insulating GaN substrate, a microlayer of GaN, a microlayer of InGaN, a first layer of GaN, a second layer of AlGaN, and a third (cap) layer of GaN, with a 2DEG formed along or adjacent to the heterojunction between the first and second layers.

FIG. 8 is a cross-sectional schematic illustration of a multi-layer electronic structure according to a fifth embodiment substantially similar to the third embodiment illustrated in FIG. 6, but with the addition of one microlayer layer each of GaN and InGaN disposed between the semi-insulating GaN substrate layer and the first GaN layer, with a 2DEG formed along or adjacent to the nanolayer of AlN.

FIG. 9 is a cross sectional schematic illustration of a multi-layer electronic structure according to a sixth embodiment substantially similar to the second embodiment illustrated in FIG. 2B, but with the addition of an InGaN channel disposed between the first layer of GaN and the second layer of AlGaN, with a 2DEG formed in the InGaN layer.

FIG. 10 is an atomic force microscopy scan of the surface of a multi-layer electronic structure including an AlGaN/GaN heterostructure grown on a semi-insulating GaN substrate.

FIG. 11 is a plot of capacitance versus voltage obtained by mercury probe capacitance-voltage measurement for an electronic structure including an AlGaN/GaN heterostructure grown on a semi-insulating GaN substrate.

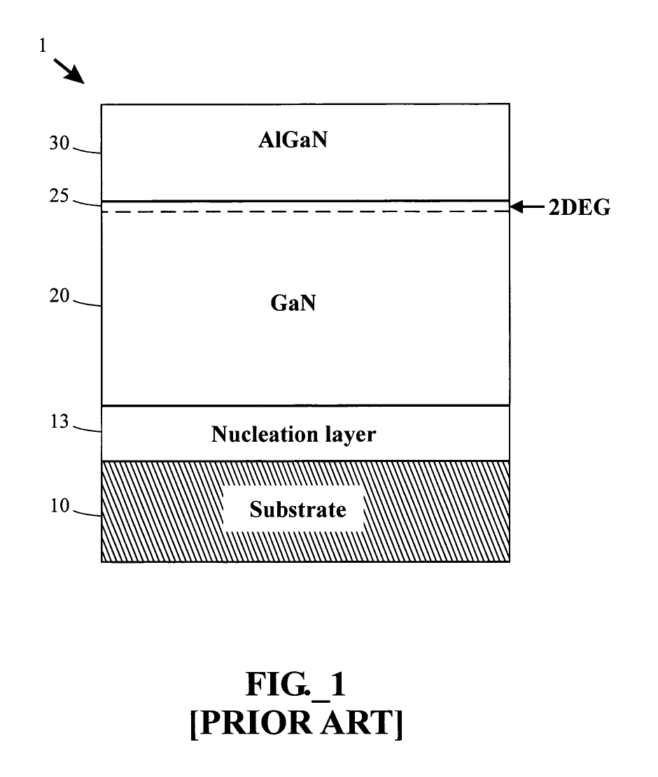

### DETAILED DESCRIPTION OF THE INVENTION, AND PREFERRED EMBODIMENTS THEREOF

The disclosures of the following patents and patent applications are hereby incorporated herein by reference, in their respective entireties:

U.S. patent application Publication No. 2005/0009310 published Jan. 12, 2005 for “Semi-insulating GaN and Method of Making the Same;”

U.S. Pat. No. 5,679,152 issued Oct. 21, 1997 for “Method of Making a Single Crystal Ga*N Article;”

U.S. Pat. No. 6,156,581 issued Dec. 5, 2000 for “GaN-Based Devices Using (Ga, Al, In)N Base Layers;”

U.S. Pat. No. 6,440,823 issued Aug. 27, 2002 for “Low Defect Density (Ga, Al, In)N and HVPE Process for Making Same;”

U.S. Pat. No. 6,447,604 issued Sep. 10, 2002 for “Method for Achieving Improved Epitaxy Quality (Surface Texture and Defect Density) on Free-Standing (Aluminum, Indium, Gallium) Nitride ((Al, In, Ga)N) Substrates for Opto-Electronic and Electronic Devices;”

U.S. Pat. No. 6,488,767 issued Dec. 3, 2002 for “High Surface Quality GaN Wafer and Method of Fabricating Same;”

U.S. Pat. No. 6,533,874 issued Mar. 18, 2003 for “GaN-Based Devices Using Thick (Ga, Al, In)N Base Layers;”

U.S. Pat. No. 6,596,079 issued Jul. 22, 2003 for “III-nitride Substrate Boule and Method of Making and Using the Same;”

U.S. Pat. No. 6,765,240 issued Jul. 20, 2004 for “Bulk Single Crystal Gallium Nitride and Method of Making Same;”

U.S. patent application Publication No. 2001/0008656 published Jul. 19, 2001 for “Bulk Single Crystal Gallium Nitride and Method of Making Same;”

U.S. patent application Publication No. 2002/0028314 published Mar. 7, 2002 for “Bulk Single Crystal Gallium Nitride and Method of Making Same;” and

U.S. patent application Publication No. 2002/0068201 published Jun. 6, 2002 for “Free-Standing (Al, In, Ga)N and Parting Method for Forming Same.”

The term “semi-insulating” as used herein and applied to a material refers to the property of having a sufficiently high resistivity to render it suitable for use as a substrate in an electronic device structure. A semi-insulating material should have a resistivity (at device-operation temperature) of preferably at least about 1×10³ ohm-cm, more preferably at least about 1×10⁴ ohm-cm, and more preferably still at least about 1×10⁵ ohm-cm. For substrates of III-nitride materials, if insufficiently pure and high crystalline quality cannot be produced, deep acceptor dopant species such as Mn, Fe, Co, Ni, Cu, or the like are preferably included to compensate unintended donor species in the AlₓGa_{y}In_{z}N and impart at least semi-insulating character to the substrate.

In accordance with the present invention, the performance of microelectronic device structures including dissimilar III-nitride device layers are improved by the use of native substrates, while formation of non-channel charges is avoided and their impact minimized through epilayer design.

In structures including a substrate, a first layer, and a second layer, with the first layer and second layer comprising different III-nitrides, the growth of a thin first layer lattice-matched to an adjacent semi-insulating native substrate has been discovered to achieve high quality III-nitride layer structures with improved performance characteristics while avoiding the above-mentioned difficulties with controlling non-channel charges. The thickness of the first III-nitride (e.g., GaN) layer grown adjacent to the substrate (e.g., SI GaN) is preferably less than about 1000 nm, more preferably less than about 500 nm, and still more preferably less than about 200 nm.

In contrast, GaN layers in conventional HEMT devices utilizing foreign substrates are relatively thick—typical thicknesses are in the range of 2 to 3 microns. One reason for the use of such thick GaN layers is to reduce dislocation density or increase material quality to improve device performance. As noted previously, nucleation layers are commonly used in GaN-based HEMT devices to mitigate lattice mismatch between GaN layers and non-native substrates; however, nucleation layers fail to eliminate lattice mismatch problems entirely. Through various dislocation elimination mechanisms, epitaxial growth of GaN layers can significantly reduce dislocation density, with the dislocation density decreasing as the epilayer thickness increases. The rate of reduction diminishes once a certain epilayer thickness is achieved. For example, Applicants have experience with fabricating GaN-based HEMT structures on silicon carbide using nucleation layers. In Applicants' experience, the use of 3 micron thickness GaN layers is sufficient to reduce dislocation densities of approximately 1×10¹⁰ dislocations per square centimeter along the nucleation layer surface to about 5×10⁸ dislocations per square centimeter along the distal surface of a GaN layer deposited thereon.

In one of Applicants' early attempts to produce GaN-based HEMT structures using native substrates, an undoped GaN layer having a thickness of 3 microns was homoepitaxially deposited on a semi-insulating GaN substrate (containing a compensating dopant) without the use of an intermediate nucleation layer. A layer of approximately 23 nanometers of AlGaN was epitaxially grown on the GaN layer, and source, drain, and gate terminals of conductive materials were added to the structure. The gate terminal was separated from the semi-insulating substrate layer by the 3 micron thickness of the undoped GaN layer. To Applicants' surprise, the resulting device exhibited non-channel charge effects, and the device performed poorly. It is believed that the non-channel charge permitted a secondary conductive channel to form between the undoped GaN layer and the semi-insulating GaN substrate, with the secondary channel not subject to being pinched off by signals from the gate terminal due to the thick (3 micron) undoped GaN layer.

In GaN-based HEMT structures utilizing semi-insulating GaN substrates, the growth of thinner GaN layers on such substrates according to the present invention substantially eliminates the problem of controlling conduction effects arising from non-channel charge. The thickness of the GaN layer is preferably less than about 1000 nm, more preferably less than about 500 nm, and still more preferably less than about 200 nm. It is believed that secondary conductive channels remain present in such devices, but that the reduction in the thickness of the GaN layer permits signals from a less-distant gate terminal to pinch off the secondary channels. Preferably, the non-channel charge is reduced as much as possible through techniques known to one skilled in the art. Such techniques include, for example, properly finishing and cleaning the surface, optimizing the choice of conditions associated with ramping to growth, carefully choosing and controlling growth conditions, and/or utilizing compensating impurities. The non-channel charge, which may be present in any of the substrate and the first layer outside the two-dimensional electron gas, is preferably less than about 1×10¹³ cm⁻²; more preferably less than about 1×10¹² cm⁻², and still more preferably less than about 1×10¹¹ cm⁻².

A thin GaN layer in a HEMT device provides further advantages in addition to facilitating control of secondary conductive channels. Reducing the thickness of a GaN layer increases sheet resistance and permits it to more closely conform to the surface of the underlying GaN substrate. Preferably, the substrate is treated with a chemical mechanical polishing (CMP) process (such as disclosed in U.S. Pat. No. 6,488,767) and then cleaned prior to the growth of the first GaN layer. When a CMP process is used on a GaN substrate and a thin GaN layer is grown thereon, the smooth layers and sharp heterojunction interface leads to improved electron mobility and sheet charge confinement of the resulting 2DEG, thus enhancing frequency response and general electrical characteristics of the resulting device.

GaN is a polar crystal, and the c-plane has two different surfaces. One surface is terminated with gallium and other surface is terminated with nitrogen for the c-plane substrates. The direction of the wafer surface can be exactly parallel to the c-axis, or can be tilted at a small angle (e.g., ≦10 degrees) with respect to the crystalline c-plane. Such plane is called a vicinal plane. Epitaxial device layers suitable for use in a HEMT are preferably grown on the gallium side of the c-plane substrates or on the vicinal plane substrates. Other materials and other orientations, however, might be employed. Assuming a wafer comprising AlₓGa_{y}In_{z}N, wherein 0≦x≦1, 0≦y≦1, 0≦z≦1, and x+y+z=1, the wafer surface may be selected from the group consisting of: AlₓGa_{y}In_{z}-terminated surfaces of AlₓGa_{y}In_{z}N in an (0001) orientation, offcuts of AlₓGa_{y}In_{z}-terminated surfaces of AlₓGa_{y}In_{z}N in an (0001) orientation, offcuts of N-terminated surfaces of AlₓGa_{y}In_{z}N in an (0001) orientation, A-plane surfaces, M-plane surfaces, R-plane surfaces, offcuts of A-plane surfaces, offcuts of M-plane surfaces and offcuts of R-plane surfaces.

Although discussion herein is directed primarily to AlGaN and GaN as illustrative III-nitride species for application of the present invention, it will be recognized that the invention is broadly applicable to III-nitride compounds, including binary compounds and alloys. As used herein, the term “III-nitride” refers to semiconductor material including nitrogen and at least one of Al, In and Ga. Such III-nitride material may be denoted symbolically as AlₓGa_{y}In_{z}N wherein 0≦x≦1, 0≦y≦1, 0≦z≦1, and x+y+z=1. The term AlₓGa_{y}In_{z}N includes all permutations of nitrides including one or more of Al, In and Ga, and thus encompasses as alternative materials AlN, InN, GaN, AlInN, AlGaN, InGaN and AlInGaN, wherein the stoichiometric coefficients of Al, In, and Ga in compounds containing two, or all three, of such metals may have any appropriate values between 0 and 1 with the proviso that the sum of all such stoichiometric coefficients is 1. In this respect, impurities such as hydrogen or carbon, dopants, or strain-altering materials such as boron can also be incorporated in the AlₓGa_{y}In_{z}N material, but the sum of all stoichiometric coefficients is 1 within a variation of ±0.1%. Examples of such compounds include AlₓGa₁₋ₓN wherein 0≦x≦1, and AlₓIn_{y}Ga_{1-x-y}N wherein 0≦x≦1 and 0≦y≦1. Thus, although the ensuing discussion is directed to GaN and AlGaN as illustrative materials, other III-nitride materials may likewise be employed in microelectronic device structures according to the invention.

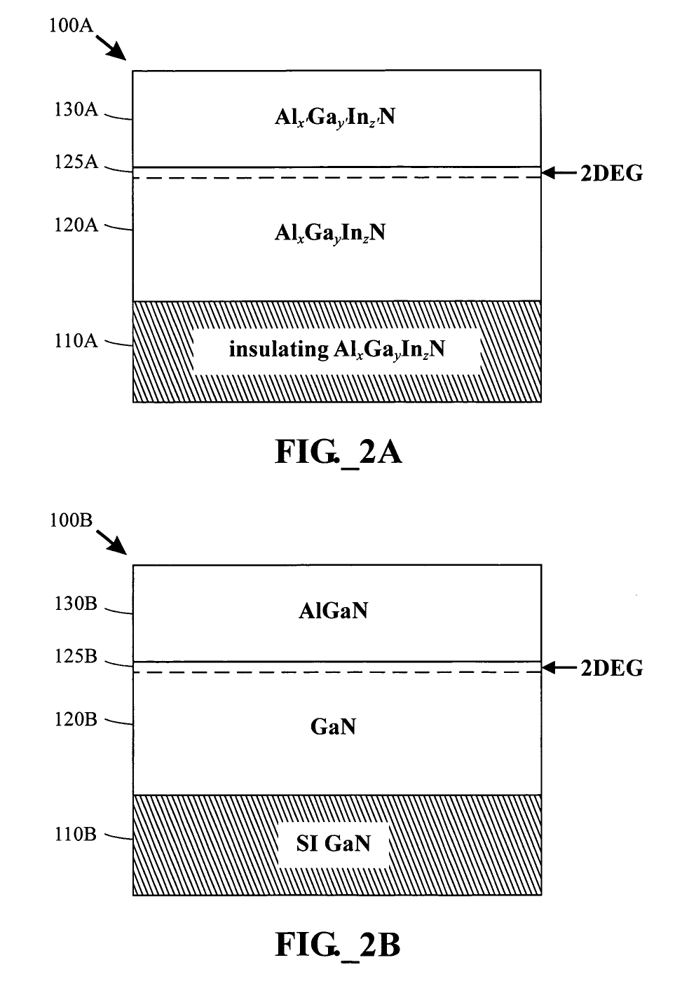

A multi-layer microelectronic device structure 100A according to a first embodiment is illustrated in FIG. 2A. An insulating substrate 110A comprising AlₓGa_{y}In_{z}N, wherein 0≦x≦1, 0≦y≦1, 0≦z≦1, and x+y+z=1, is provided. Preferably, the substrate 110A has a surface dislocation density of less than about 1×10⁷ dislocations per square centimeter and a room temperature resistivity of at least about 1×10⁵ ohms per centimeter. Examples of semi-insulating substrates exhibiting such properties and fabrication methods therefor are disclosed in commonly assigned U.S. Patent Application Publication No. 2005/0009310. The substrate 110A is preferably polished (e.g., using, for example, a finishing polishing process such as a CMP process) and then cleaned. A first device layer 120A comprising AlₓGa_{y}In_{z}N is grown on the substrate 110A without the use of an intermediate nucleation layer. The first layer 120A preferably has a surface dislocation density of less than about 1×10⁷ dislocations per square centimeter. Thereafter, a second device layer 130A comprising Al_{x′}Ga_{y′}In_{z′}N, wherein 0≦x′≦1, 0≦y′≦1, 0≦z′≦1, and x′+y′+z′=1, is grown on the first device layer 120A. The materials and thicknesses of the first layer 120A and the second layer 130A are selected to form a two-dimensional electron gas 125A along or adjacent to a surface of at least one of the first layer 120A and the second layer 130A.

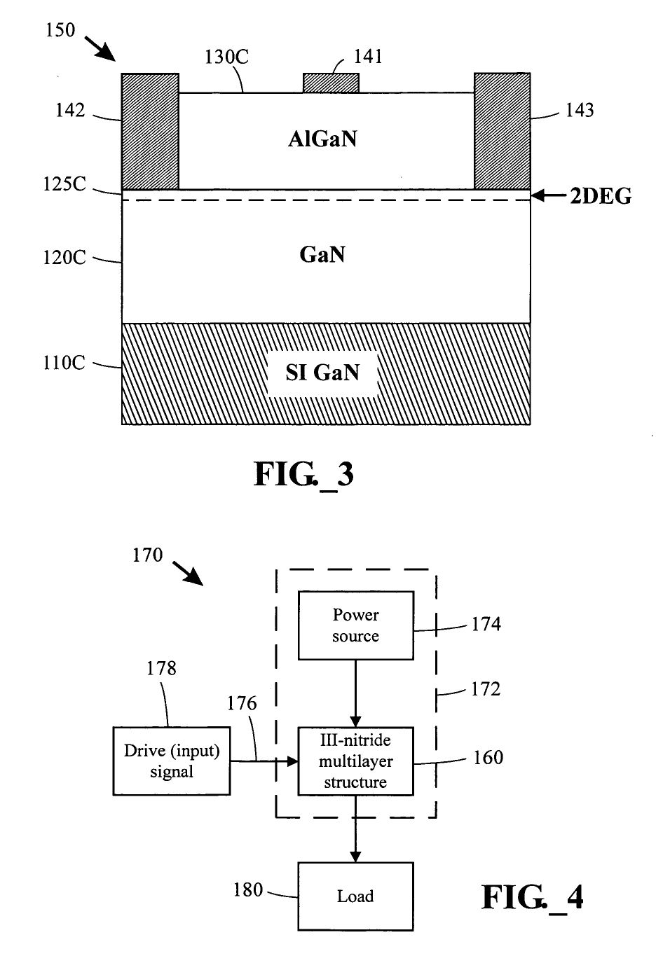

Any appropriate growth technique may be used to grown the first and second device layers 120A, 130A. For example, processes such as metal organic vapor phase epitaxy (MOVPE) (also known as metal organic chemical vapor deposition (MOCVD)), hydride vapor phase epitaxy (HVPE), atomic layer epitaxy (ALE), or molecular beam epitaxy may be used. At least one conductive terminal (such as the terminals 141-143 shown in FIG. 3) is preferably provided and disposed on or in any of the first, second, and substrate layers 110A, 120A, 130A.

An embodiment representing a subset of the multi-layer structure of FIG. 2A is illustrated in FIG. 2B. A multi-layer electronic device structure 100B includes a semi-insulating GaN substrate layer 110B, a first layer 120B comprising GaN grown on the gallium surface of the substrate 110B, and a second layer 130B comprising AlGaN grown on the first layer 120B. A 2DEG 125B is formed along the interface between the first layer 120B and the second layer 130B. If the AlGaN alloy is represented as AlₓGa_{y}N, preferably 0.1≦x≦0.5, and more preferably 0.2≦x≦0.4. The thickness of the second layer 130B should be limited to the critical thickness that the second AlGaN layer 130B is pseodumorphic (i.e., not relaxed) on the first GaN layer 120B. The critical thickness of the second AlGaN layer 130B depends on the Al percentage present in the alloy, with higher Al contents typically leading to lower critical thicknesses of the second AlGaN layer 130B on a GaN first layer 120B. The thickness of the second AlGaN layer 130B is preferably in a range of from about 10 nm to about 40 nm, more preferably from about 20 nm to about 30 nm. The second AlGaN layer 130B may be undoped, doped, or delta doped, or doped according to any suitable doping profile to enhance the performance of the electronic device structure 100B for a desired application.

In another embodiment, a HEMT device that incorporates the structure 100B of FIG. 2B is provided. Referring to FIG. 3, a HEMT device 150 includes a semi-insulating GaN substrate 110C. A first thin (e.g., less than about 1000 nm) GaN layer 120C is homoepitaxially grown on the substrate 110C, and a second AlGaN layer 130C is epitaxially grown on the first layer 120C to form a 2DEG 125C along the heterointerface between the first and second layers 120C, 130C. Three terminals 141-143 are provided, with the central terminal 141 serving as a first (gate) terminal 141 to control current flow from a second (source) terminal 142 to a third (drain) terminal 143. While the device 150 is directed to providing functionality as a HEMT including three terminals 141-143 with the first terminal 141 disposed on the third layer 130C, and with the second and third terminals 142, 143 disposed on the second layer 120C and/or in the first layer 130C, it is to be appreciated that device structures according to the present invention include at least one terminal in electrical communication, more preferably in electrical contact, with the 2DEG 125C.

In another embodiment illustrated in FIG. 4, a microelectronic device includes a III-nitride multi-layer device structure 160. The electronic device 170 preferably includes a power source 174 and a fixture 176 for inputting a signal 178 to be amplified to the III-nitride multi-layer device structure 160, with any of the foregoing components 160, 174, and 176 disposed in or on an appropriate housing or support element 172. The electronic device 170 receives an input signal and generates an output signal with the aid of the III-nitride multi-layer device structure 160. The III-nitride multi-layer device structure 160 is preferably a HEMT. Examples of microelectronic devices according to this embodiment include power amplifiers, broadcast transmitters, power converters, audio amplifiers, and wireless communication devices such as mobile telephone and personal data assistants. Additionally, such electronic devices may be incorporated into desirable systems such as phased array radar systems and wireless communication base stations.

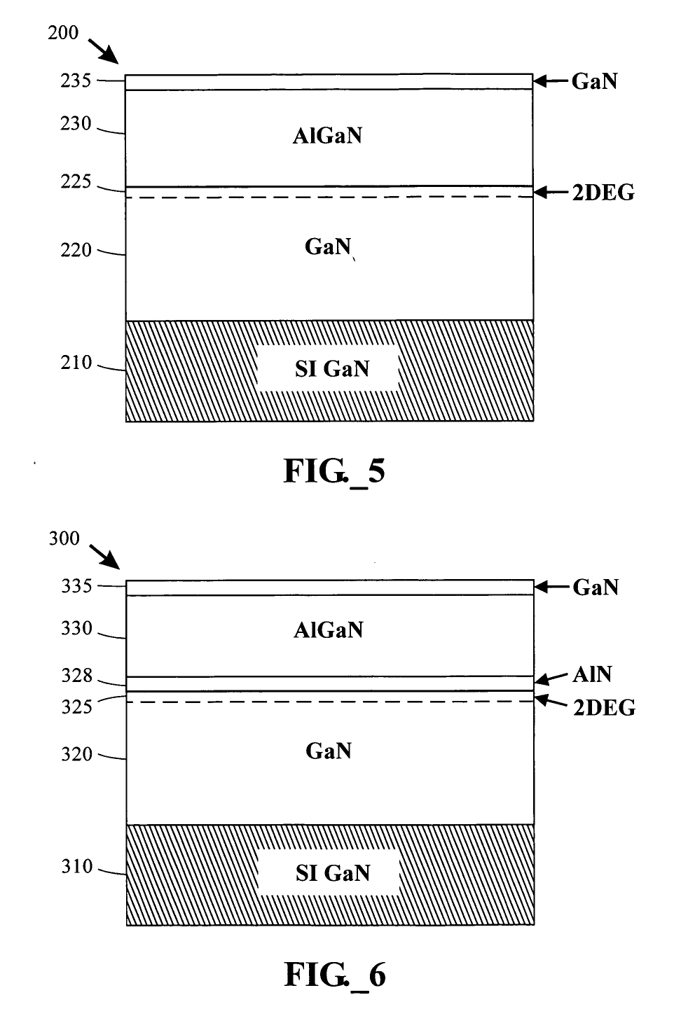

In another embodiment, a cap layer is added to a III-nitride multi-layer device structure having a thin (e.g., ≦1000 nm) first layer and a native substrate. Referring to FIG. 5, a III-nitride multi-layer device structure 200 includes a semi-insulating GaN substrate 210 and a thin first GaN layer 220 homoepitaxially grown on the gallium surface of the substrate 210. A second AlGaN layer 230 is epitaxially grown on the first layer 210 to form a 2DEG 225 along the heterointerface between the first and second layers 220, 230. Thereafter, a very thin third GaN cap layer 235, preferably less than about 10 nm thick, is epitaxially grown on the second layer 230. The third GaN cap layer 235 functions to significantly increase the surface barrier height to reduce gate leakage current and thereby improve the performance of the resulting device structure. The third GaN cap layer 235 may, however, slightly reduce the density of the 2DEG 225.

In yet another embodiment, a fourth layer may be disposed between the dissimilar III-nitride material layers to serve as an intermediate barrier layer along the 2DEG in a device structure having a thin first layer and a native substrate. A fourth layer may be provided whether or not a third layer (e.g., GaN cap layer 235) as described previously is also present. Referring to FIG. 6, a III-nitride multi-layer device structure 300 includes a semi-insulating GaN substrate 310 and a thin first GaN layer 320 homoepitaxially grown on the gallium surface of the substrate 310. An intermediate III-nitride barrier layer 328 is then grown on the first GaN layer 320. A preferred material for the fourth layer 328 is AlN. If AlN is used, the thickness of the fourth layer 328 is preferably less than about 2 nanometers, more preferably in a range from about 0.5 nanometers to about 1.5 nanometers. The second AlGaN layer is grown on the fourth layer 328, with the combination of the first GaN layer 320 and the second AlGaN layer 330 being adapted to form a 2DEG 325 that is enhanced by the fourth layer 328. The fourth layer 328 reduces the alloy scattering and increases confinement of the 2DEG by increasing the conduction band offset. The fourth layer increases the 2DEG density by elevating the polarization difference between GaN and AlGaN, thus improving the performance of the structure 300. Optionally, a third GaN cap layer 335 may be grown on the second layer 330 to increase surface barrier height. The incorporation of both a third GaN cap layer 335 and the fourth AlN intermediate barrier layer 328 promotes increased surface barrier height, higher 2DEG density, better 2DEG confinement, and less alloy scattering and reduce gate leakage current in the resulting device structure 300.

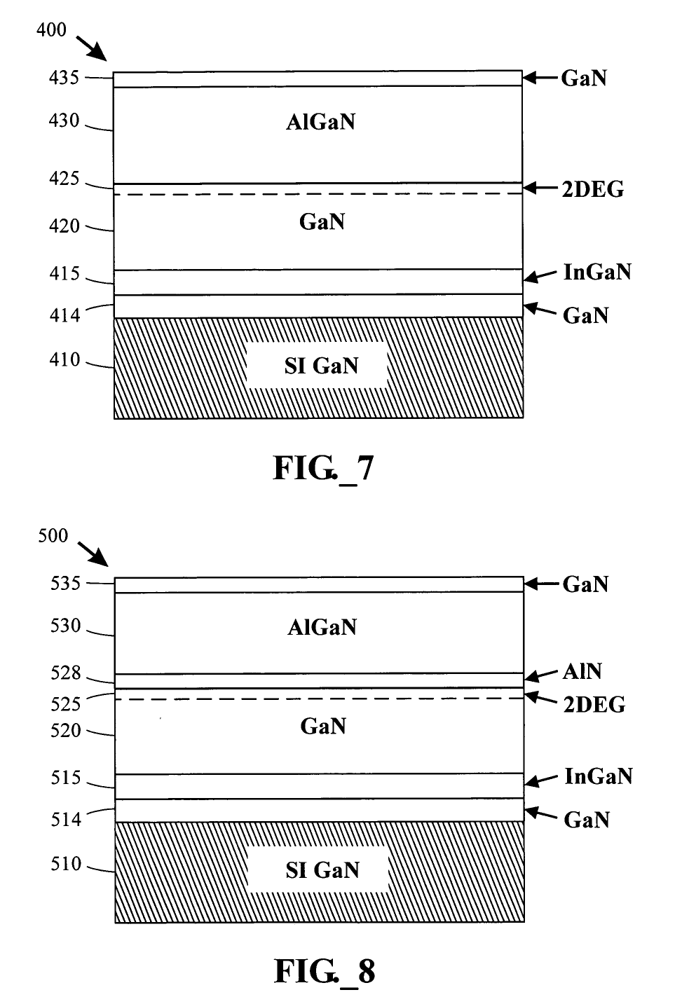

In still another embodiment, a fifth layer may be disposed between the substrate and the first GaN layer to serve as an additional bottom electron barrier. Referring to FIG. 7, a III-nitride multi-layer device structure 400 includes a semi-insulating GaN substrate 410. A fifth layer 415 of an electron barrier material may be grown directly on the gallium surface of a semi-insulating GaN substrate 410. More preferably, however, a thin (e.g., about 10 nm in thickness) sixth layer 414 of a material such as insulating GaN is homoepitaxially grown on the gallium surface of the SI GaN substrate 410 to serve as a buffer, and the fifth electron barrier layer 415 is grown on the sixth layer 414. The composition and thickness of the fifth layer 415 should not cause the structural relaxation of the fifth layer 415 on the InGaN on GaN. A preferred material for the fifth layer 415 is InGaN. If InGaN is used, then the thickness of the fifth layer 415 is preferably less than about 50 nm, and In preferably represents less than about 20% of the metal within the alloy.

Following formation of the fifth layer 415, a first GaN layer 420 is grown on the fifth layer 415, and a second AlGaN layer 430 is then grown on the first layer 420 to form a 2DEG 425 along the heterointerface. Optionally, a third GaN cap layer 435 may be grown on the second layer 430 to increase surface barrier height. Because of the discontinuity of polarization between the first GaN layer 420 and the fifth InGaN electron barrier layer 415, an electric field develops in the fifth layer 415 that reduces the probability that hot electrons may escape from the first layer 420 and become trapped in the sixth layer 414 (if present) and/or substrate layer 410, thus improving performance of the device structure 400.

In yet another embodiment, a III-nitride multi-layer device structure including a thin first layer and a native substrate may include any combination of or all of the enhancements illustrated in and described in connection with FIGS. 5-7. Referring to FIG. 8, a III-nitride multi-layer device structure including a substrate layer 510, first layer 520, and second layer 530, may further include: a third cap layer 535 adjacent to the second layer 530; a fourth layer disposed between the first layer 520 and the second layer 530 to serve as an intermediate barrier along the 2DEG 525; a fifth layer 515 disposed between the first layer 520 and the substrate 510 to serve as a bottom electron barrier; and (in combination with the fifth layer 520), a sixth layer 514 to serve as a buffer between the substrate 510 and the fifth layer 515.

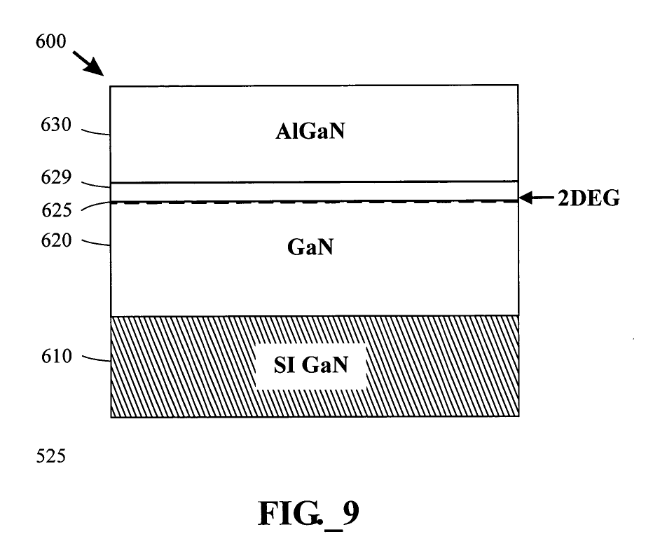

In another embodiment, a seventh layer may be disposed between the dissimilar III-nitride material layers (first and second layers) to serve as a channel defining layer to facilitate improved 2DEG transport. The seventh layer may be provided whether or not a third layer (e.g. a GaN cap layer), a fourth layer (e.g. and AlN interlayer), a fifth layer (electron barrier) and/or a sixth layer (initiation layer) as described previously are also present. Referring to FIG. 9, a III-nitride multi-layer device structure 600 includes a semi-insulating GaN substrate 610 and a thin first GaN layer 620 homoepitaxially grown on the gallium surface of the substrate 610. An intermediate III-nitride channel layer 629 with a bandgap energy less than the first layer is then grown on the first GaN layer 620. A preferred material for the seventh layer 629 is Ga_{y}In_{z}N in which y+z=1 and preferably 0<z<0.1. If Ga_{y}In_{z}N in which y+z=1 and preferably 0<z<0.1 is used, the thickness of the seventh layer 629 is preferably greater than about 2 nanometers and preferably less than 20 nm. The second AlGaN layer is grown on the seventh layer 629, with the combination of the first GaN layer 620 and the second AlGaN layer 630 being adapted to form a 2DEG 625 that forms in the seventh layer 629. The seventh layer 629 enables improved charge transport and confinement of the 2DEG.

One skilled in the art could envision altering and/or combining various aspects of these embodiments to produce further innovative structures on insulating III-nitride substrates. For example, a first approach may include fabricating a first layer from a larger bandgap material than GaN (e.g., by increasing defect or impurity ionization energy) to improve electron confinement. A second approach may include doping the first layer (e.g., GaN) or the fifth or sixth layers with a compensating impurity such as Mg, Fe, Zn, or the like to increase the resistance of these layers. A third approach may include fabricating a first layer from an AlInGaN material of appropriate composition to create an electric field to suppress deleterious hot electron effects. A fourth approach may include fabricating a first layer from an AlInGaN lattice matched quaternary alloy. Various other alterations and combinations will be apparent to the skilled artisan upon reviewing the present disclosure.

The advantages and features of the invention are further illustrated with reference to the following examples, which are not to be construed as in any way limiting the scope of the invention but rather as illustrative of various embodiments of the invention in specific applications thereof.

### EXAMPLE 1

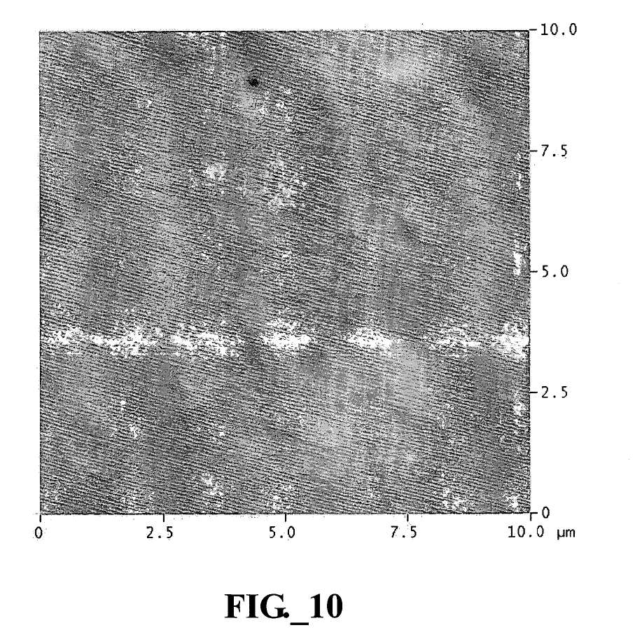

A first III-nitride multi-layer device structure of the type shown schematically in FIGS. 2A-2B was constructed with a c-plane SI GaN substrate. The structure was grown by MOCVD using ammonia as the nitrogen source and TMG (trimethylgallium) and TMA (trimethylaluminum) as the gallium and aluminum sources, respectively. A cleaned, c-plane SI GaN substrate was loaded into a reactor and heated to the growth temperature. Growth began once the reactor reached the growth temperature, without anneal or nucleation steps. A 100 nm thickness first GaN layer was grown on the substrate with the following process conditions: a susceptor temperature of 1220C (note that substrate temperature is typically about 50-200C lower than the susceptor temperature), a growth pressure of 100 mbar, and a growth rate of about 2 μm/hr. The aluminum source was then turned on and a 10 nm thickness second AlGaN layer was grown on the first layer with the percentage of Al in the second layer being about 24% of the metal in the nitride alloy. The aluminum and gallium sources were then turned off, and the wafer was cooled. FIG. 10 shows an atomic force microscopy (AFM) image of the surface of the second AlGaN layer. The root mean square (RMS) roughness of this surface is less than 3 Angstroms, compared with a typical value greater than 5 Angstroms for HEMT structures grown on SiC and sapphire substrates.

### EXAMPLE 2

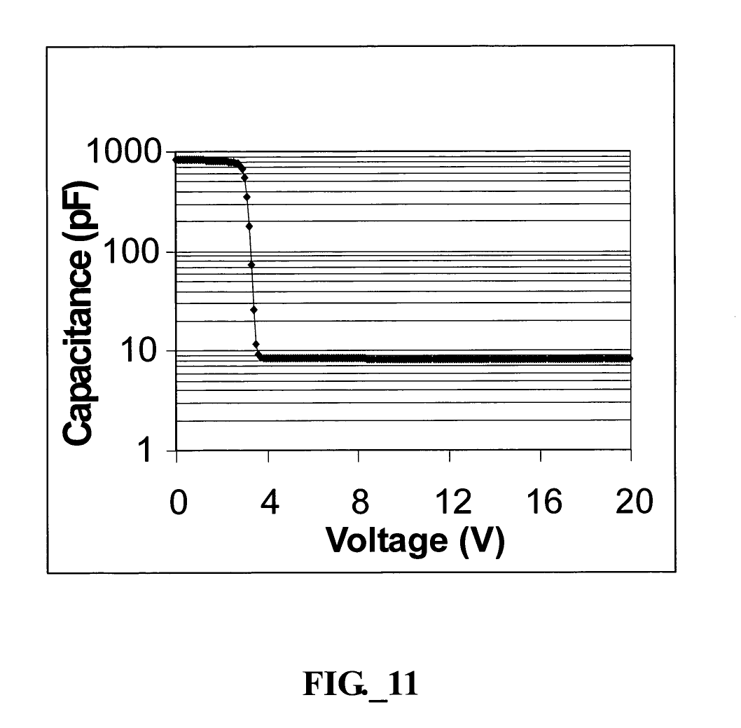

A second III-nitride multi-layer device structure of the type shown schematically in FIGS. 2A-2B was constructed with a vicinal SI GaN substrate. The structure was grown by MOCVD using ammonia as the nitrogen source, TMG as the gallium source, and TMA as the aluminum source. A cleaned, vicinal SI GaN substrate was loaded into a reactor and heated to the growth temperature. The vicinal substrate was offcut by 1 degree toward the <10-10> direction. Growth began once the reactor reached the growth temperature, without anneal or nucleation steps. A 50 nm thickness first GaN layer was grown on the substrate with the following process conditions: a susceptor temperature of 1170C, a growth pressure of 100 mbar, and a growth rate of about 2 μm/hr. The aluminum source was then turned on and a 10 nm thickness second AlGaN layer was grown on the first layer with the percentage of Al in the second layer being about 24% of the metal in the nitride allow. The aluminum and gallium sources were then turned off, and the wafer was cooled. A Hall measurement was performed on this wafer and it had a sheet concentration of about 6.5×10¹² per square centimeter with a mobility greater than 1400 cm²V⁻¹s⁻¹. FIG. 11 shows a mercury probe capacitance-voltage measurement of the multi-layer device structure, showing a sharp pinch-off.

### EXAMPLE 3

A III-nitride multi-layer structure of the type shown schematically in FIG. 5 (i.e., including a GaN cap layer) was constructed. The structure was grown by MOCVD using ammonia as the nitrogen source, TMG as the gallium source, and TMA as the aluminum source. A cleaned, c-plane SI GaN substrate was loaded into a reactor and heated to the growth temperature. Growth began once the reactor reached the growth temperature, without anneal or nucleation steps. The growth conditions for all layers were: a susceptor temperature of 1170C, a growth pressure of 100 mbar, and a growth rate of about 2 μm/hr. The initial growth was that of a 100 nm thickness first GaN layer on the substrate. The aluminum source was then turned on and a 22 nm thickness second AlGaN layer was grown on the first layer, with the percentage of Al in the second layer being about 27% of the metal in the nitride alloy. The aluminum source was then turned off, and a 2 nm thickness third GaN cap layer was grown on the second layer. The gallium source was then turned off, and the wafer was cooled. The surface of this wafer was imaged with an atomic force microscopy (AFM). The root mean square (RMS) roughness of the resulting surface is less than 3 Angstroms, compared with a typical value of greater than 5 Angstroms for HEMT structures grown on SiC and sapphire substrates. A Hall measurement was performed on this wafer and it had a sheet concentration of about 2.3×10¹³ cm⁻² with a mobility greater than 800 cm²V⁻¹s⁻¹.

### EXAMPLE 4

A III-nitride multi-layer structure of the type shown schematically in FIG. 6 (but without the optional third GaN cap layer) was constructed, with the structure having a fourth intermediate barrier layer of AlN disposed between the first GaN layer and the second AlGaN layer. The structure was grown by MOCVD using ammonia as the nitrogen source, TMG as the gallium source, and TMA as the aluminum source. A cleaned, c-plane SI GaN substrate was loaded into a reactor and heated to the growth temperature. Growth began once the reactor reached the growth temperature, without anneal or nucleation steps. The growth conditions for the first GaN layer and the second AlGaN layer were: a susceptor temperature of 1170C, a growth pressure of 100 mbar, and a growth rate of about 2 μm/hr. The growth conditions for the fourth AlN layer were the same as for the first and second layers except for the growth rate, which was about 0.3 μm/hr. The initial growth was that of a 100 nm thickness first GaN layer on the substrate. The gallium source was then turned off, and after a 5 second delay the aluminum source was turned on. A 1 nm thickness fourth AlN layer was then grown on the first layer. The gallium source was then turned on and a 25 nm thickness second AlGaN layer was grown on the first layer with the percentage of Al in the second layer being about 25% of the metal in the nitride alloy. The gallium and aluminum sources were then turned off, and the wafer was cooled. A Hall measurement was performed on this wafer and it had a sheet concentration of about 2×10¹³ cm⁻² with a mobility greater than 1000 cm²V⁻¹s⁻¹. While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

What is claimed is:

1. An electronic device structure comprising:
a substrate layer comprising semi-insulating AlₓGa_{y}In_{z}N, wherein 0≦x≦1, 0≦y≦1, 0≦z≦1, and x+y+z=1;
a first layer comprising AlₓGa_{y}In_{z}N;
a second layer comprising Al_{x′}Ga_{y′}In_{z′}N, wherein x′+y′+z′=1; and
at least one terminal comprising a conductive material;
wherein the first layer is disposed between the second layer and the substrate layer, and the first layer and the second layer in combination are adapted to form a two-dimensional electron gas.

2. The structure of claim 1 wherein the first layer is homoepitaxially grown on the substrate layer.

3. The structure of claim 1 wherein the first layer is lattice-matched to the substrate layer without the use of an intermediate nucleation layer.

4. The structure of claim 1, wherein the first layer has a thickness of less than about 1000 nanometers.

5. The structure of claim 1, wherein the first layer has a thickness of less than about 500 nanometers.

6. The structure of claim 1, wherein the first layer has a thickness of less than about 200 nanometers.

7. The structure of claim 1 wherein the substrate has a surface dislocation density of less than about 1×10⁷ dislocations per square centimeter.

8. The structure of claim 1 wherein:
the at least one terminal comprises three terminals; and
any of the following are selected to permit modulation of a secondary current flow path distinct from the two-dimensional electron gas a terminal of the three terminals: thickness of any of the first layer and the second layer; defect density of any of the substrate layer and the first layer; and stoichiometry of the first layer and the second layer.

9. The structure of claim 1 wherein any of the substrate and the first layer outside the two-dimensional electron gas has a charge of less than about 1×10¹³ cm⁻².

10. The structure of claim 1 wherein any of the substrate and the first layer outside the two-dimensional electron gas has a charge of less than about 1×10¹² cm⁻².

11. The structure of claim 1 wherein any of the substrate and the first layer outside the two-dimensional electron gas has a charge of less than about 1×10¹¹ cm⁻².

12. The structure of claim 1 wherein the first layer comprises a compensating dopant.

13. The structure of claim 1 wherein the substrate has a room temperature resistivity greater than about 1×10⁵ ohms-cm.

14. The structure of claim 1 wherein the second layer has a surface dislocation density of less than about 1×10⁷ dislocations per square centimeter.

15. The structure of claim 1 wherein the substrate comprises a compensating dopant.

16. The structure of claim 15 wherein the compensating dopant concentration is in a range of from about 3×10¹⁶ to about 7×10¹⁷ atoms per cubic centimeter.

17. The structure of claim 16 wherein the compensating dopant comprises any of Mn, Fe, Co, Ni, and Cu.

18. The structure of claim 1 wherein y=1, z′=0, and x′≧0.1.

19. The structure of claim 1 wherein 0.1≦x′≦0.5.

20. The structure of claim 1 wherein 0.2≦x′≦0.4.

21. The structure of claim 1 wherein the second layer has a thickness in a range of from about 10 nanometers to about 40 nanometers.

22. The structure of claim 1 wherein the second layer has a thickness in a range of from about 20 nanometers to about 30 nanometers.

23. The structure of claim 1, further comprising a third layer comprising AlₓGa_{y}In_{z}N, wherein the second layer is disposed between the first layer and the third layer.

24. The structure of claim 23 wherein the third layer has a thickness of less than about 10 nanometers.

25. The structure of claim 23 wherein y=1.

26. The structure of claim 24 wherein the third layer is adapted to increase surface barrier height.

27. The structure of claim 1, further comprising a fourth layer comprising Al_{x″}Ga_{y″}In_{z″}N, wherein:
x″+y″+z″=1; and
the fourth layer is disposed between the first layer and the second layer.

28. The structure of claim 27 wherein the fourth layer has a thickness in a range of from about 0.5 nanometer to about 2 nanometers.

29. The structure of claim 27 wherein x″=1.

30. The structure of claim 27 wherein the fourth layer is adapted to increase any of the density and the confinement of the two dimensional electron gas.

31. The structure of claim 1, further comprising a fifth layer comprising Al_{x′″}Ga_{y′″}In_{z′″}N, wherein:
x′″+y′″+z′″=1; and
the fifth layer is disposed between the first layer and the substrate.

32. The structure of claim 31 wherein the fifth layer has a thickness of less than about 50 nanometers.

33. The structure of claim 31 wherein x′″=0.

34. The structure of claim 31, further comprising a sixth layer comprising AlₓGa_{y}In_{z}N disposed between the fifth layer and the substrate, wherein the sixth layer is lattice-matched to the substrate.

35. The structure of claim 34, wherein any of the fifth layer and the sixth layer further comprises a compensating dopant.

36. The structure of claim 1 wherein:
the substrate layer comprises at least about 99.99999 percent AlₓGa_{y}In_{z}N;
the first layer comprises at least about 99.99999 percent Al_{x′}Ga_{y′}In_{z′}N; and
the second layer comprises at least about 99.99999 percent AlₓGa_{y}In_{z}N.

37. The structure of claim 1 wherein the at least one terminal comprises a plurality of terminals.

38. The structure of claim 1 wherein the at least one terminal is in electrical communication with the two dimensional electron gas.

39. The structure of claim 37 wherein a terminal of the plurality of terminals is in electrical contact with the two dimensional electron gas.

40. A high electron mobility transistor device comprising the structure of claim 37.

41. An electronic device comprising the structure of claim 38.

42. A phased array radar system comprising the electronic device of claim 41.

43. A wireless communication base station comprising the electronic device of claim 41.

44. An electronic device structure comprising:
a semi-insulating substrate layer comprising a first III-nitride material;
a first layer comprising the first III-nitride material;
a second layer comprising a second III-nitride material, the second III-V material being distinct from the first III-V material; and
at least one terminal comprising a conductive material;
wherein the first layer is disposed between the substrate layer and the second layer, and the first layer and the second layer are adapted to form a two-dimensional electron gas.

45. The structure of claim 44 wherein each of the first layer and the second layer is epitaxially grown.

46. The structure of claim 44 wherein the first layer is lattice-matched to the substrate layer without the use of an intermediate nucleation layer.

47. The structure of claim 44, wherein the first layer has a thickness of less than about 500 nanometers.

48. The structure of claim 44 wherein the first layer has a surface dislocation density of less than about 1×10⁷ dislocations per square centimeter.

49. The structure of claim 44, further comprising a third layer comprising the first III-nitride material, wherein the second layer is disposed between the first layer and the third layer.

50. The structure of claim 44, further comprising a fourth layer comprising a third III-nitride material, wherein the fourth layer is disposed between the first layer and the second layer.

51. The structure of claim 44, further comprising a fifth layer comprising a fourth III-nitride material, wherein the fifth layer is disposed between the first layer and the substrate.

52. The structure of claim 51, further comprising a sixth layer comprising the first III-nitride material, wherein the sixth layer is disposed between the fifth layer and the substrate, and the sixth layer is lattice-matched to the substrate.

53. The structure of claim 44 wherein the at least one terminal is in electrical communication with the two dimensional electron gas.

54. An electronic device comprising the structure of claim 53.

55. A phased array radar system comprising the electronic device of claim 54.

56. A wireless communication base station comprising the electronic device of claim 54.

57. An electronic device structure comprising:
a semi-insulating substrate layer comprising a first III-nitride material;
an epitaxially grown first layer comprising the first III-nitride material, the first layer being lattice-matched to the substrate layer without the use of an intermediate nucleation layer;
an epitaxially grown second layer comprising a second III-nitride material; and
at least one terminal comprising a conductive material;
wherein the first layer and the second layer define a heterojunction adapted to form a two dimensional electron gas.

58. The structure of claim 57, wherein the first layer has a thickness of less than about 500 nanometers.

59. The structure of claim 57 wherein the first layer has a surface dislocation density of less than about 1×10⁷ dislocations per square centimeter.

60. The structure of claim 57 wherein first III-nitride material is GaN and the second III-nitride material layer is AlGaN.

61. The structure of claim 57 wherein the first layer is disposed between the second layer and the substrate layer.

62. The structure of claim 57 wherein the at least one terminal is in electrical contact with the two dimensional electron gas.

63. An electronic device comprising the structure of claim 62.

64. A phased array radar system comprising the electronic device of claim 63.

65. A wireless communication base station comprising the electronic device of claim 63.

66. A method of fabricating a microelectronic device structure, the method comprising the steps of:
providing a semi-insulating substrate comprising AlₓGa_{y}In_{z}N, wherein 0≦x≦1, 0≦y≦1, 0≦z≦1, and x+y+z=1;
epitaxially growing a first layer comprising AlₓGa_{y}In_{z}N on or adjacent to the substrate, the first layer being lattice-matched to the substrate;
epitaxially growing a second layer comprising Al_{x′}Ga_{y′}In_{z′}N, wherein 0≦x′≦1, 0≦y′≦1, 0≦z′≦1, and x′+y′+z′=1, on or adjacent to the first layer, wherein the first layer and the second layer are adapted to form a two dimensional electron gas; and
depositing at least one terminal comprising a conductive material in electrical communication with the two dimensional electron gas.

67. The method of claim 66 wherein y=1, z′=0, and x′≧0.1.

68. The method of claim 66 wherein the substrate comprises a compensating dopant in a concentration range of from about 3×10¹⁶ to about 7×10¹⁷ atoms per cubic centimeter.

69. The method of claim 66 wherein the first layer has a thickness of less than about 500 nanometers.

70. The method of claim 66 wherein the first layer has a thickness of less than about 200 nanometers.

71. The method of claim 66 wherein the first layer has a surface dislocation density of less than about 1×10⁷ dislocations per square centimeter.

72. The method of claim 66, further comprising the step of chemical-mechanical polishing at least one surface of the substrate prior to the first layer growth step.

73. The method of claim 66, further comprising the step of growing a third layer comprising AlₓGa_{y}In_{z}N on the second material layer.

74. The method of claim 73 wherein y=1.

75. The method of claim 66, further comprising the step of growing a fourth layer comprising Al_{x″}Ga_{y″}In_{z″}N, wherein x″+y″+z″=1, on the first layer.

76. The method of claim 75 wherein x″=1.

77. The method of claim 66, further comprising the step of growing a fifth layer comprising Al_{x′″}Ga_{y′″}In_{z′″}N, wherein:
x′″+y′″+z′″=1; and
the fifth layer is disposed between the first layer and the substrate.

78. The method of claim 77 wherein x′″=0.

79. The method of claim 77, further comprising the step of growing a sixth layer comprising AlₓGa_{y}In_{z}N, wherein the sixth layer is disposed between the fifth layer and the substrate, and the sixth layer is lattice-matched to the substrate.

80. The method of claim 66 wherein steps of growing any of the first layer and the second layer are performed using metal organic vapor phase epitaxy.

81. The method of claim 66 wherein steps of growing any of the first layer and the second layer are performed using atomic layer epitaxy.

82. The method of claim 66 wherein steps of growing any of the first layer and the second layer are performed using molecular beam epitaxy.

83. The method of claim 66 wherein:
the at least one terminal comprises three terminals; and
any of the following are selected to permit modulation of a secondary current flow path distinct from the two-dimensional electron gas a terminal of the three terminals: thickness of any of the first layer and the second layer; defect density of any of the substrate layer and the first layer; and stoichiometry of the first layer and the second layer.

84. An electronic device structure fabricated according to the method of claim 66.

85. An electronic device comprising the structure of claim 84.

86. A phased array radar system comprising the electronic device of claim 85.

87. A wireless communication base station comprising the electronic device of claim 85.
